(19) United States
(12) Patent Application Publication
(10) Pub. No.: US 2019/0222163 A1
(43) Pub. Date: Jul. 18, 2019

(54) MOUNTING SYSTEMS FOR SOLAR PHOTOVOLTAIC (PV) POWER PLANTS

(71) Applicant: Alion Energy, Inc., Richmond, CA (US)

(72) Inventors: Søren Jensen, Corte Madera, CA (US); Luigi Petrigh-Dove, Petaluma, CA (US); Aaron M. Spindell, Fairfax, CA (US)

(21) Appl. No.: 16/246,216

(22) Filed: Jan. 11, 2019

Related U.S. Application Data
(60) Provisional application No. 62/616,996, filed on Jan. 12, 2018.

(51) Int. Cl. H02S 20/22; H01L 31/042; F24S 25/634; F24S 25/33

(52) U.S. Cl. CPC H02S 20/22; H01L 31/042; F24S 2025/02; F24S 25/33; F24S 25/634

(57) ABSTRACT

A support structure for a fixed-tilt solar collector comprises front and rear concrete ballasts extending in a direction parallel to a row of one or more PV panels and a racking structure configured to support the one or more PV panels such that a normal vector of the one or more PV panels is at a fixed angle. At least one stringer is arranged in a direction parallel to the front and rear concrete ballasts. First and second rails are arranged in a direction perpendicular to the stringers. The first and second rails are fastened to and support the at least one stringer. The first and second rails are fastened to the front concrete ballast. Legs are fastened to and support at least one of i) the at least one stringer or ii) the first and second rails. The legs are fastened to the rear concrete ballast.

### CROSS-REFERENCE TO RELATED APPLICATION

This application claims priority to U.S. Provisional Application No. 62/616,996, filed Jan. 12, 2018, the entirety of which is herein incorporated by reference.

### FIELD

The current subject matter is directed to aspects relating to solar PV mounting systems for use in solar PV power plants.

### BACKGROUND

Solar PV power plants use PV panels to collect light from the sun and convert it into electric power. An important feature of the power plant design is to position the panels at a desired orientation for many years without human intervention. A variety of technical and financial variables are considered to decide what the orientation is. In some cases, the solar panels are fixed in place, aligned in rows, and tilted with respect to zenith, defined as pointing up from the ground. In other cases, the solar panels are rotated to track the sun as it moves across the sky. Either way, a racking structure usually is required to support the solar panels. The racking structure often needs to resist wind forces, seismic forces, ground settlement, and/or snow loads to maintain the desired position of the solar panels for the life of the power plant.

### SUMMARY

A support structure for a fixed-tilt solar collector is provided herein. The support structure for the fixed-tilt solar collector comprises front and rear concrete ballasts extending in a direction parallel to a row of one or more PV panels. The support structure for the fixed-tilt solar collector further comprises a racking structure configured to support the one or more PV panels such that a normal vector of the one or more PV panels is at a fixed angle relative to a zenith. The racking structure comprises at least one stringer arranged in a direction parallel to the front and rear concrete ballasts. The racking structure further comprises first and second rails arranged in a direction perpendicular to the stringers. The first and second rails are fastened to and support the at least one stringer. The first and second rails are fastened to the front concrete ballast. The racking structure further comprises legs fastened to and supporting at least one of i) the at least one stringer or ii) the first and second rails. The legs are fastened to the rear concrete ballast.

A method for assembling a support structure for a fixed-tilt solar collector is provided herein. In that method, a front concrete ballast and a rear concrete ballast are formed. A racking structure configured to support a row of one or more PV panels such that a normal vector of the one or more PV panels is at a fixed angle relative to a zenith, is assembled. The assembling comprises fastening a first end of each of first and second legs to the rear concrete ballast. First and second rails are positioned in a direction perpendicular to the front and rear concrete ballasts. A second end of the first leg is fastened to the first rail. A second end of the second leg is fastened to the second rail. The first and second rails are fastened to the front concrete ballast. One or more stringers are positioned in a direction parallel to the front and rear concrete ballasts. The one or more stringers are fastened to at least one of i) the second end of the first leg and the second end of the second leg or ii) the first and second rails. The front and rear concrete ballasts extend in a direction parallel to the row of the one or more PV panels.

A fixed-tilt solar collector is provided herein. The fixed-tilt solar collector comprises a row of one or more PV panels, a front concrete ballast and a rear concrete ballast extending in a direction parallel to the row, and a racking structure configured to support the row of one or more photovoltaic PV panels such that a normal vector of the one or more PV panels is at a fixed angle relative to a zenith. The racking structure comprises stringers arranged in a direction parallel to the front and rear concrete ballasts. The racking structure further comprises a first rail and a second rail arranged in a direction perpendicular to the stringers and the one or more concrete ballasts. The first and second rails are fastened to and support the stringers. The first and second rails each comprises two bent-up tabs that fit within walls of a groove in the front concrete ballast. The racking structure further comprises legs each comprising a first end and a second end. The first end is fastened to and supports at least one of i) one of the stringers or ii) the first and second rails. The second end comprises a foot. The foot fits inside of a groove of the rear concrete ballast.

### BRIEF DESCRIPTION OF FIGURES

FIG. 1 shows a perspective view of a front of a fixed tilt solar collector for a solar PV power plant.

FIG. 2 shows a perspective view of a rear of the fixed tilt solar of FIG. 1.

FIG. 3 shows a perspective view of a front foot joint.

FIG. 4 features a perspective view of a rear foot joint.

FIG. 5 shows a perspective view of the joint between a stringer, a rail, and a leg.

FIG. 6 shows a perspective view of a portion of a solar field.

FIG. 7 is a flow diagram depicting steps to assemble a solar collector.

FIG. 8 shows a perspective view of the front of a fixed tilt solar collector.

FIG. 9 shows a perspective view of the rear of the fixed tilt solar collector of FIG. 8.

FIG. 10 shows a perspective view of the front of a fixed tilt solar collector.

FIG. 11 shows a perspective view of the rear of the fixed tilt solar collector of FIG. 10.

FIGS. 12A, 12B, and 12C depict an assembly comprising a rail and a leg.

FIG. 13 shows a perspective view of the rear of the fixed tilt solar collector wherein legs are cast into concrete.

FIG. 14 is a flow diagram depicting a method for assembling a support structure for a fixed-tilt solar collector.

### DETAILED DESCRIPTION

Certain embodiments of a fixed-tilt solar collector are described herein. Some embodiments of the structural systems and the methods for assembling them are also described.

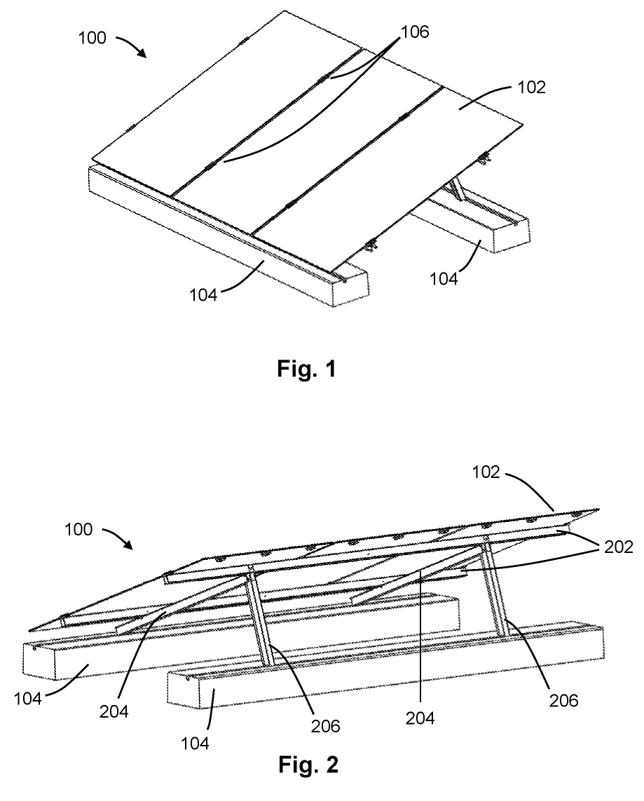

FIG. 1 shows a perspective view of a front of a fixed tilt solar collector 100 for a solar PV power plant. The solar collector includes PV panels 102 supported by a racking structure, which is fastened to a concrete foundation. In FIG. 1, the normal vector of the panels is angled at 20° versus zenith; however, the same design could be used with trivial modifications to accommodate angles ranging between 0° (pointing up) and 60°. The foundation includes two concrete ballasts 104. The concrete ballasts 104 can be made from pre-cast blocks, made by casting in place, and/or by slip-forming. Three PV panels are shown, but more or fewer could be used with the same design. In FIG. 1, clips 106 are shown which fasten the PV panels 102 onto the racking structure. For example, the PV panels are made with a metal frame, and/or with no frame where two glass pieces sandwich the active PV material. The clips 106 could be clamps that fasten onto the metal frame of the PV panels if they have frames, or the clips could be clamps that fasten on glass if the PV panels do not have frames.

FIG. 2 shows a perspective view of a rear of the fixed tilt solar collector 100 of FIG. 1. The PV panels 102 and the concrete ballasts 104 are shown, along with a series of structural members that connect them. The clips 106, shown in FIG. 1, fasten the PV panels 102 onto two stringers, front and rear stringers 202, which are arranged, for example, parallel to the concrete ballasts 104. Framed PV panels can alternatively be fastened by securing panel frames directly to the stringers 202 with fasteners without clips 106. The rails 204 fasten to the front concrete ballasts 104, and the two stringers 202 can fasten to the rails. The legs 206 can fasten to the rear concrete ballast 104 and to the rear stringer 202. The solar collector angle can be configured for a power plant project by setting the lengths of the rails 204 and the legs 206 and by setting the spacing between the concrete ballasts 104. The stringers 202, the rails 204, and legs 206 can be made of metal, plastic, wood, a synthetic wood material, and/or any other suitable material that meets strength, stiffness, longevity, and/or other parameters.

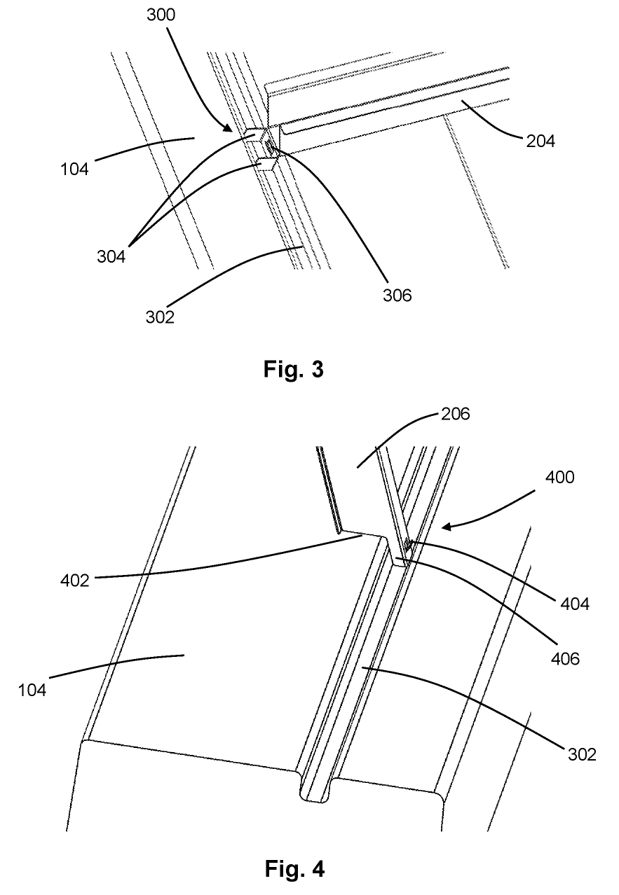

FIG. 3 shows a perspective view of a front foot joint 300. The front foot joint 300 can include an adhesive joint between the rail 204 and the concrete ballast 104. The end of the rail 204 is bent such that it fits within the walls of a groove 302 in the concrete ballast 104. This bent section can include two bent-up tabs 304 and a third bent out tab 306. This third tab 306 is formed by bending out a piece of the rail 204 such that a hole opens in the rail 204. Adhesive is applied around the three tabs and fully across the groove 302 in the concrete ballast 104. The adhesive flows through the hole in the rail, over the three tabs, and from one wall of the groove to the other. This results in, for example, a strong joint where the solidified adhesive forms a mechanical lock through the hole and above the tabs so that the adhesive would have to fracture for the joint to fail.

FIG. 4 features a perspective view of a rear foot joint 400. For example, the leg 206 has a notch removed 402 at an end such that the remaining portion of the leg 206—a rear foot 406—can fit within the groove 302 in the concrete ballast 104. The end of the leg 206 can also have a tab 404 formed by bending out a piece of the leg 206 such that a hole is opened through the leg 206. Adhesive forms the foot joint 400 by adhering the leg 206 to the groove 302 in the concrete ballast 104. In one example, the adhesive is deposited to flow through the hole, above the tab, and fully across the groove 302 such that it forms a mechanical lock on the leg 206 and so that it adheres to both walls of the groove 302 for greater strength. In another example, for the leg to break free from the adhesive, the adhesive would have to fracture.

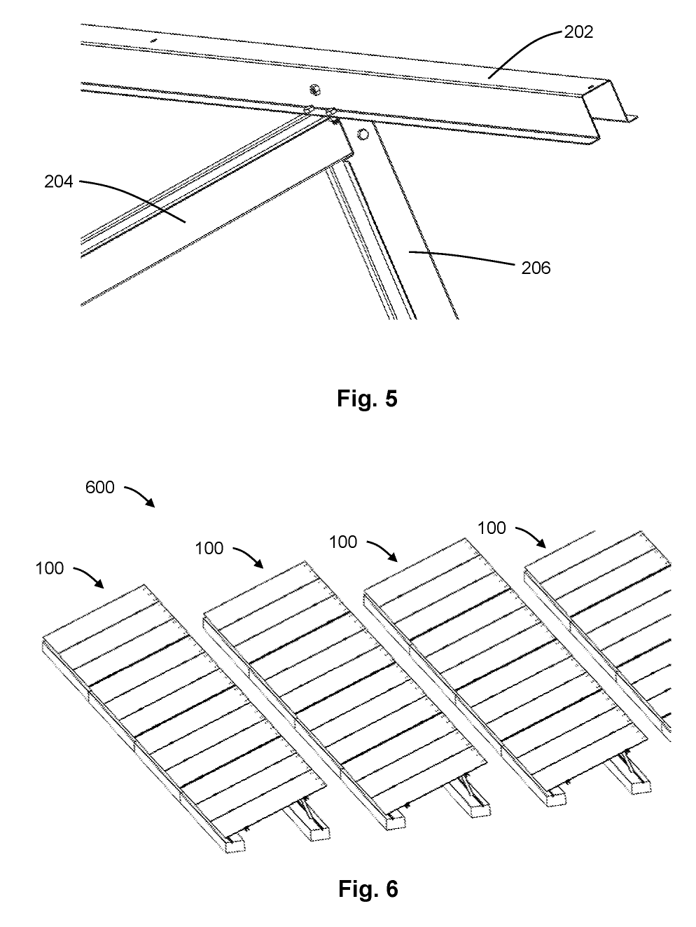

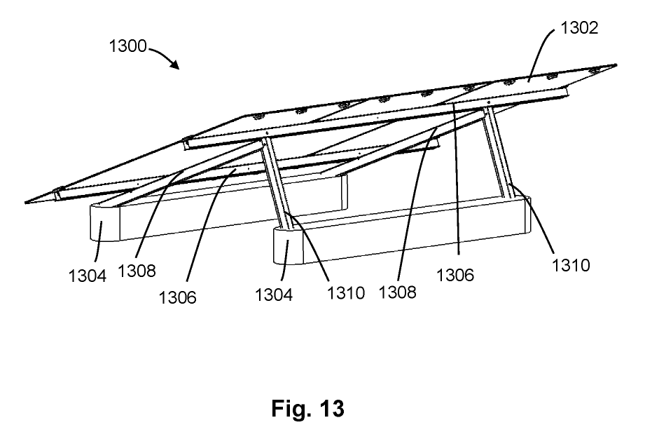

With respect to FIGS. 4 and 5, the front foot joint 300 and/or the rear foot joint 400 can include other types of j oints. As one example, the front foot joint 300 and/or the rear foot joint 400 can be wet-set into concrete by letting the concrete harden around a metal that sticks out of the concrete. This example is shown in FIG. 13. As another example, a fastener could be used to secure a foot part to already-formed concrete.

FIG. 5 shows a perspective view of the joint between the stringer 202, the rail 204, and the leg 206. The PV panels 102 and the clamps 106 are omitted for clarity. The stringer 202 can fasten directly to the rail 204. In another example, the stringer 202 can fasten to the leg 206. In another example, a part located inside the leg 206 fastens to the leg and provides a surface for the stringer 202 to fasten to.

FIG. 6 shows a perspective view of a portion of a solar field 600. The solar collector 100 of FIG. 1 is repeated in a direction transverse to the concrete ballasts, repeated at regular intervals. The PV panels can be wired together and combined with other equipment as appropriate to send power to the grid or to a load. For example, the solar collectors can each use individual concrete sections as ballast. In another example, the solar collectors share concrete sections, as can be formed by a slip-form paver. If long, continuous pieces of concrete are used, controls joints can be cut in the concrete at regular intervals between solar collectors to mitigate crack formation.

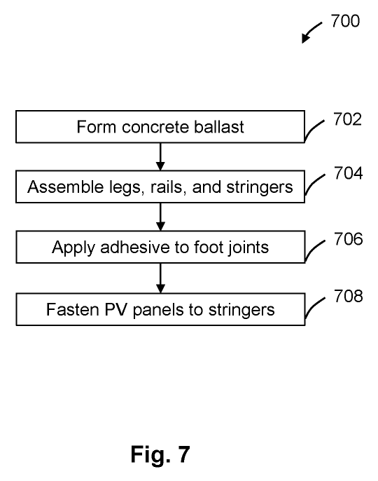

FIG. 7 shows the steps to assemble the solar collector 100 shown in FIG. 1. A method of assembling a solar collector includes processes 702, 704, 706, and 708. First, at process 702, concrete ballast is formed or placed. Next, at process 704, the legs 206, the rails 204, and the stringers 202 are assembled. Third, at process 706, adhesive is applied to the front foot joints 300 and the rear foot joints 400. Fourth, at process 708, the PV panels 102 are fastened to the stringers 202.

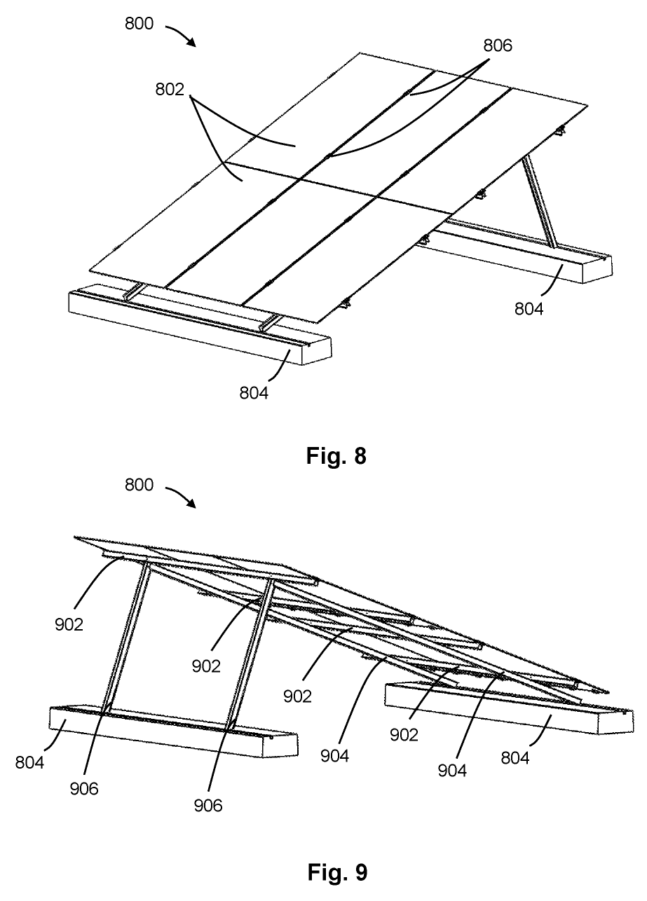

FIG. 8 shows a perspective view of a front of a fixed tilt solar collector 800 for a solar PV power plant. For example, the solar collector includes PV panels 802 supported by a racking structure, which is fastened to a concrete foundation. The foundation includes two concrete ballasts 804. The concrete ballasts can be made from pre-cast blocks, made by casting in place, and/or by slip-forming. The PV panels 802 are arranged in a row that extends in a direction parallel to the two concrete ballasts 804. The PV panels 802 are also arranged in a column that extends in a direction perpendicular to the two concrete ballasts 804. In this example, the row comprises three PV panels, and the column comprises two PV panels, but more or fewer could be used with the same design. In FIG. 8, clips 806 are shown which fasten the PV panels 802 onto the racking structure. For example, the PV panels 802 are made with a metal frame, and/or with no frame where two glass pieces sandwich the active PV material. The clips 806 could be clamps that fasten onto the metal frame of the PV panels if they have frames, or the clips 806 could be clamps that fasten on glass if the PV panels do not have frames. Framed PV panels can alternatively be fastened by securing panel frames to stringers with fasteners without clips 806.

FIG. 9 shows a perspective view of a rear of the fixed tilt solar collector 800 of FIG. 8. The PV panels 802 and the concrete ballasts 804 are shown, along with a series of structural members that connect them. The clips 806, shown in FIG. 8, fasten the PV panels 802 onto four stringers 902 which are arranged, for example, parallel to the concrete ballasts 804. The four stringers 902 are supported by two rails 904 and two legs 906. The rails 904 fasten to the front concrete ballasts 804, and the four stringers 902 fasten to the rails. The legs 206 can fasten to the rear concrete ballast 804 and to the rear stringer 902. The solar collector angle can be configured for a power plant project by setting the lengths of the rails 904 and the legs 906 and by setting the spacing between the concrete ballasts 804. The stringers 902, the rails 904, and legs 906 can be made of metal, plastic, wood, a synthetic wood material, and/or any other suitable material that meets strength, stiffness, longevity, and/or other parameters.

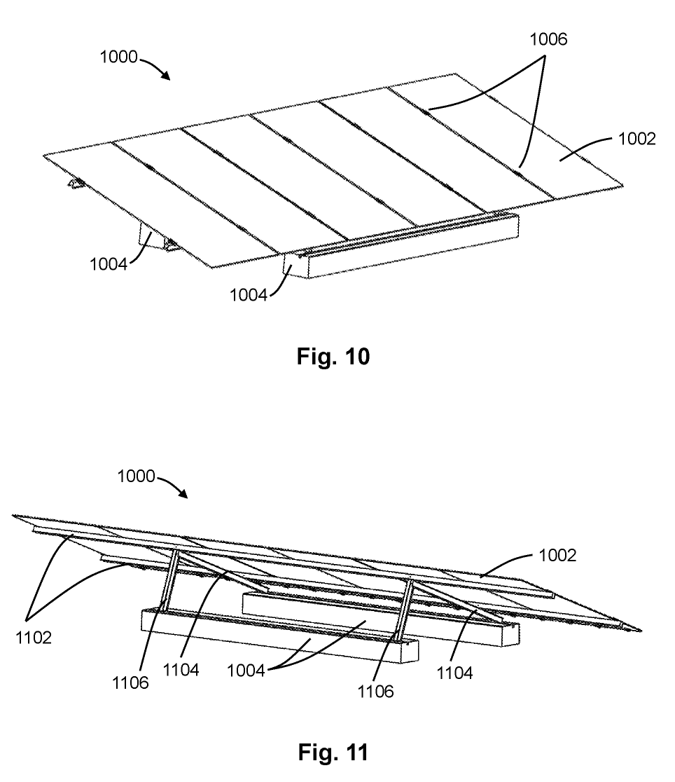

FIG. 10 shows a perspective view of a front of a fixed tilt solar collector 1000 for a solar PV power plant. For example, the solar collector includes PV panels 1002 supported by a racking structure, which is fastened to a concrete foundation. The foundation includes two concrete ballasts 1004. The concrete ballasts can be made from pre-cast blocks, made by casting in place, and/or by slip-forming. The PV panels 1002 are arranged in a row that runs parallel to the two concrete ballasts 1004. In this embodiment, the concrete ballasts 1004 do not extend to ends of the row of the PV panels 1002. If a second fixed tilt solar collector 1000 was to be placed adjacent to the fixed tilt solar collector 1000, such that row of PV panels 1002 was extended, the concrete ballasts of the two solar collectors would not touch each other and would form a discontinuous line. In FIG. 10, clips 1006 are shown which fasten the PV panels 1002 onto the racking structure. For example, the PV panels are made with a metal frame, and/or with no frame where two glass pieces sandwich the active PV material. The clips 1006 could be clamps that fasten onto the metal frame of the PV panels if they have frames, or the clips 1006 could be clamps that fasten on glass if the PV panels do not have frames.

FIG. 11 shows a perspective view of the rear of the fixed tilt solar collector 1000 of FIG. 10. The PV panels 1002 and the concrete foundation ballasts 1004 are shown, along with a series of structural members that connect them. The clips 1006, shown in FIG. 10, fasten the PV panels 1002 onto two stringers 1102 which are arranged, for example, parallel to the concrete ballasts. The two stringers 1102 are supported by two rails 1104 and two legs 1106. The rails 1104 fasten to the front concrete ballasts 1004, and the two stringers 1102 fasten to the rails. The legs 1106 can fasten to the rear concrete ballast 1004 and to the rear stringer 1102. The solar collector angle can be configured for a power plant project by setting the lengths of the rails 1104 and the legs 1106 and by setting the spacing between the concrete ballasts 1004. The stringers 1102, the rails 1104, and legs 1106 can be made of metal, plastic, wood, a synthetic wood material, and/or any other suitable material that meets strength, stiffness, longevity, and/or other parameters.

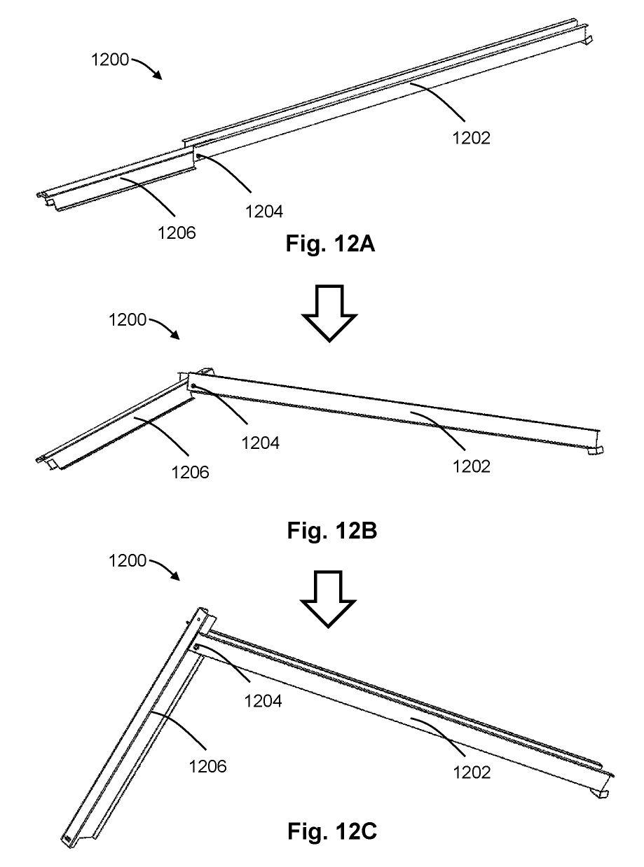

FIGS. 12A, 12B, and 12C depict an assembly 1200 comprising a rail 1202 and a leg 1206. The arrows indicate a progression between FIGS. 12A, 12B, and 12C. The rail 1202 and leg 1206 can be pre-assembled with a hinge joint 1204. The hinge joint 1204 can be a fastener used to connect the leg to the inserted piece, or it can be another fastener or hinge. The rail 1202 and leg 1206 can be shipped or moved around the job site in a parallel position, as in FIG. 12A. Then, rail 1202 and leg 1206 can be rotated with respect to one another at the hinge joint 1204, as shown in FIG. 12B. The rail 1202 and leg 1206 can be rotated into a perpendicular position for installation, as shown in FIG. 12C. The location of the hinge 1204 and surfaces of the leg 1206 and rail 1202 are configured so that the rail 1202 and leg 1206 surfaces make positive contact in both the parallel and perpendicular positions. In this way, the correct angle in each position is assured.

FIG. 13 shows a perspective view of the rear of a fixed tilt solar collector 1300 wherein rails and legs are cast into concrete. PV panels 1302 and concrete ballasts 1304 are shown, along with a series of structural members that connect them. The PV panels 1302 are fastened onto two or more stringers 1306 which are arranged, for example, parallel to the concrete ballasts 1304. The two stringers 1306 are supported by two rails 1308 and two legs 1310. The rails 1304 can be secured into the front concrete ballasts 1304 by pouring wet concrete around the end of the rail and allowing the concrete to harden around it. The two or more stringers 1306 can fasten to the rails. The legs 1310 can fasten to the rear concrete ballast 1304 by pouring wet concrete around the end of the legs 1310 and allowing the concrete to harden around them. and the legs 1310 can fasten to the rear stringer 1306.

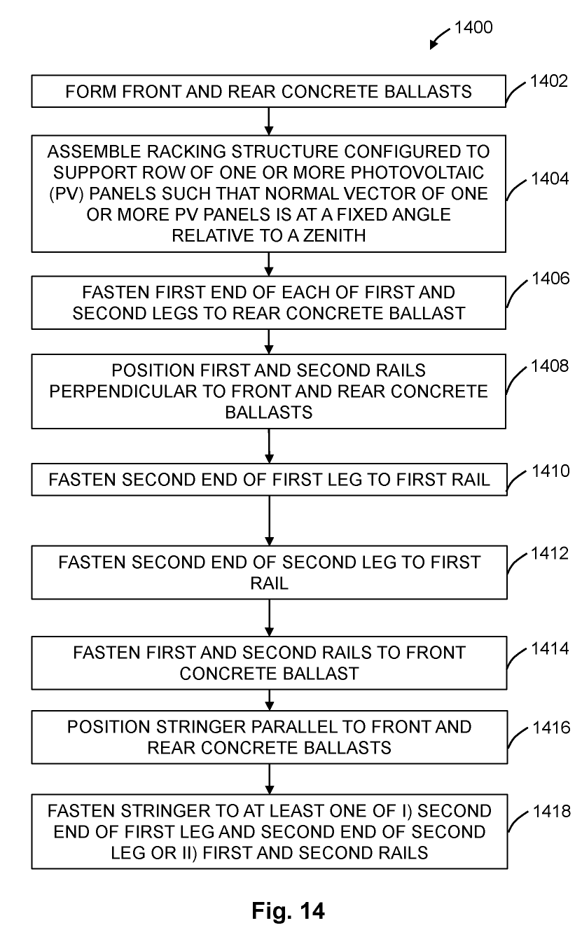

FIG. 14 is a flow diagram depicting a method for assembling a support structure for a fixed-tilt solar collector. At 1402, a front concrete ballast and a rear concrete ballast are formed. At 1404, a racking structure configured to support a row of one or more PV panels such that a normal vector of the one or more PV panels is at a fixed angle relative to a zenith, is assembled. At 1406, the assembling comprises fastening a first end of each of first and second legs to the rear concrete ballast. At 1408, first and second rails are positioned in a direction perpendicular to the front and rear concrete ballasts. At 1410, a second end of the first leg is fastened to the first rail. At 1412, a second end of the second leg is fastened to the second rail. At 1414, the first and second rails are fastened to the front concrete ballast. At 1416, one or more stringers are positioned in a direction parallel to the front and rear concrete ballasts. At 1418, the one or more stringers are fastened to at least one of the i) second end of the first leg and the second end of the second leg or ii) the first and second rails. The front and rear concrete ballasts extend in a direction parallel to the row of the one or more PV panels.

In one embodiment, the concrete ballasts 104 shown in FIG. 1 first serve the purpose of providing ballast for the solar collector 100 to prevent overturn or movement due to wind forces. For example, they also can serve a second purpose, which is to provide a track for vehicles. A track-based vehicle that can drive above the panels can use the top, outside corner of the concrete to support wheels. A track-based vehicle that can drive below the panels can use the top, inside corner of the concrete to support wheels. In another example, such a vehicle can be used for a wide variety of purposes, including transporting people and equipment, cleaning panels, clearing snow, depositing pesticide or herbicide, depositing material to increase the reflectivity of the ground, taking pictures, taking pictures in the infrared spectrum to observe temperature, depositing coatings on the racking, panels, and/or wiring, and/or making a wide variety of measurements.

In another embodiment, the racking system used in the solar collector shown in FIG. 1 features one or more design advantages over other fixed tilt solar collectors, and such one or more design advantages result in overall lower cost of electricity. For example, as stated earlier, the concrete foundation doubles as a track for driving vehicles, and this enables cost reduction in operations and maintenance tasks, such as panel cleaning. In another example, the foundation is located entirely above ground; whereas, other types of solar collectors use piles driven into the ground. The above-ground concrete foundation can avoid problems associated with very hard soil, very soft soil, and/or corrosive soil. In yet another example, the concrete ballasts provide a strong, distributed base which allows lightweight, low-cost parts to be used for other structural members (e.g., the rails 204, the legs 206, and/or the stringers 202 in FIG. 2). In some variations, such use of lightweight, low-cost parts allows significant cost reduction versus other designs that use piles that often need strong and expensive metal parts to provide main structural stiffness and strength. In another example, the stringers and concrete ballasts both extend across multiple PV panels thereby enlarging the wind load tributary area, thereby averaging out wind gusts to lower the wind-driven loads on individual structural members.

In the descriptions above and in the claims, phrases such as “at least one of” or “one or more of” can occur followed by a conjunctive list of elements or features. The term “and/or” can also occur in a list of two or more elements or features. Unless otherwise implicitly or explicitly contradicted by the context in which it is used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C;” “one or more of A, B, and C;” and “A, B, and/or C” are each intended to mean “A alone, B alone, C alone, A and B together, A and C together, B and C together, or A and B and C together.” In addition, use of the term “based on,” above and in the claims is intended to mean, “based at least in part on,” such that an unrecited feature or element is also permissible.

The subject matter described herein can be embodied in systems, apparatus, methods, and/or articles depending on the desired configuration. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. For example, the implementations described above can be directed to various combinations and subcombinations of the disclosed features and/or combinations and subcombinations of several further features disclosed above. In addition, the logic flows depicted in the accompanying figures and/or described herein do not necessarily require the particular order shown, or sequential order, to achieve desirable results. Other implementations may be within the scope of the following claims.

1. A support structure for a fixed-tilt solar collector comprising:
front and rear concrete ballasts extending in a direction parallel to a row of one or more photovoltaic (PV) panels; and
a racking structure configured to support the one or more PV panels such that a normal vector of the one or more PV panels is at a fixed angle relative to a zenith, the racking structure comprising:
at least one stringer arranged in a direction parallel to the front and rear concrete ballasts;
first and second rails arranged in a direction perpendicular to the stringers, the first and second rails fastened to and supporting the at least one stringer, the first and second rails fastened to the front concrete ballast; and
legs fastened to and supporting at least one of i) the at least one stringer or ii) the first and second rails, the legs fastened to the rear concrete ballast.

2. The support structure of claim 1, further comprising clips that fasten the one or more PV panels to the stringers.

3. The support structure of claim 1, wherein the at least one stringer, the first and second rails, and the legs comprise at least one of a metal, a plastic, a wood, or a synthetic wood material.

4. The support structure of claim 1, wherein a rear foot at an end of each of the legs fits inside of a first groove of the rear concrete ballast, wherein an end of the first and second rails is bent such that it fits within walls of a second groove in the front concrete ballast, and wherein an adhesive is applied fully across the first and second grooves to adhere the legs to the rear concrete ballast and the first and second rails to the front concrete ballast.

5. The support structure of claim 1, wherein the one or more PV panels are arranged in two rows, such that the two rows span between the front and rear concrete ballasts.

6. The support structure of claim 1, further comprising the one or more PV panels.

7. The support structure of claim 1, wherein the front and rear concrete ballasts are split into discrete tracks positioned parallel to the row.

8. The support structure of claim 1, wherein the front and rear concrete ballasts form a continuous piece of concrete.

9. The support structure of claim 1, wherein each of the first and second rails and a respective leg is preassembled into a parallel position and configured to rotate to a perpendicular position prior to installation.

10. The support structure of claim 1, wherein the front and rear concrete ballasts are formed by slip-form paving concrete, and wherein the leg and rail are coupled to the front and rear concrete ballasts via a groove comprising an epoxy joint.

11. The support structure of claim 1, wherein the front and rear concrete ballasts are formed by casting concrete in a form, and wherein the legs and the first and second rails are coupled to the concrete by casting the legs and the first and second rails into the form when the concrete is wet.

12. The support structure of claim 1, wherein the at least one stringer is substantially longer than the front and rear concrete ballasts.

13. A method for assembling a support structure for a fixed-tilt solar collector comprising:
forming a front concrete ballast and a rear concrete ballast;
assembling a racking structure configured to support a row of one or more photovoltaic (PV) panels such that a normal vector of the one or more PV panels is at a fixed angle relative to a zenith, the assembling comprising:
fastening a first end of each of first and second legs to the rear concrete ballast;
positioning first and second rails in a direction perpendicular to the front and rear concrete ballasts;
fastening a second end of the first leg to the first rail;
fastening a second end of the second leg to the second rail;
fastening the first and second rails to the front concrete ballast; and
positioning one or more stringers in a direction parallel to the front and rear concrete ballasts;
fastening the one or more stringers to at least one of i) the second end of the first leg and the second end of the second leg or ii) the first and second rails,
wherein the front and rear concrete ballasts extend in a direction parallel to the row of the one or more PV panels.

14. The method of claim 13, further comprising:
positioning a rear foot at an end of each of the legs fits inside of a first groove of the rear concrete ballast;
bending an end of the first and second rails such that the first and second rails fit within walls of a second groove in the front concrete ballast; and
applying an adhesive across the first and second grooves to adhere the legs to the rear concrete ballast and the first and second rails to the front concrete ballast.

15. The method of claim 13, wherein the one or more PV panels are arranged in two rows, such that the two rows span between the front and rear concrete ballasts.

16. The method of claim 13, wherein the forming further comprises slip-form paving the front and rear concrete ballasts, and wherein the leg and rail are coupled to the front and rear concrete ballasts via a groove comprising an epoxy joint.

17. The method of claim 13, wherein the front and rear concrete ballasts are formed into discrete tracks positioned parallel to the row.

18. The method of claim 13, wherein the one or more stringers is substantially longer than the front and rear concrete ballasts.

19. A fixed-tilt solar collector comprising:
a row of one or more photovoltaic (PV) panels;
a front concrete ballast and a rear concrete ballast extending in a direction parallel to the row; and
a racking structure configured to support the row of one or more photovoltaic PV panels such that a normal vector of the one or more PV panels is at a fixed angle relative to a zenith, the racking structure comprising:
stringers arranged in a direction parallel to the front and rear concrete ballasts;
a first rail and a second rail arranged in a direction perpendicular to the stringers and the one or more concrete ballasts, the first and second rails fastened to and supporting the stringers, the first and second rails each comprising two bent-up tabs that fit within walls of a groove in the front concrete ballast; and
legs each comprising a first end and a second end, the first end fastened to and supporting at least one of i) one of the stringers or ii) the first and second rails, the second end comprising a foot, wherein the foot fits inside of a groove of the rear concrete ballast.

20. The fixed-tilt solar collector of claim 19, wherein the front and rear concrete ballasts are split into discrete tracks positioned parallel to the row.
